(19) United States
(12) Patent Application Publication
(10) Pub. No.: US 2024/0400377 A1
(43) Pub. Date: Dec. 5, 2024

(54) MICROMECHANICAL COMPONENT FOR A SENSOR DEVICE OR MICROPHONE DEVICE

(71) Applicant: Robert Bosch GmbH, Stuttgart (DE)

(72) Inventors: Heribert Weber, Nuertingen (DE); Peter Schmollngruber, Aidlingen (DE); Sophielouise Mach, Reutlingen (DE)

(21) Appl. No.: 18/699,690

(22) PCT Filed: Oct. 19, 2022
(86) PCT No.: PCT/EP2022/079058

§ 371 Date: Apr. 9, 2024

(30) Foreign Application Priority Data
Oct. 26, 2021 (DE) 10 2021 212 038.5

(51) Int. Cl. B81B 3/00; B81C 1/00

(52) U.S. Cl. CPC B81B 3/0078; B81C 1/00666; B81B 2201/0257; B81B 2201/0264; B81B 2203/0127; B81B 2203/0307; B81B 2203/0315; B81B 2203/04; B81C 2201/0105; B81C 2201/019

(57) ABSTRACT

A micromechanical component for a sensor or microphone device. The micromechanical component includes an actuator electrode, which is adjustably arranged on and/or in a cavity and is made of silicon, and a stator electrode, which is arranged in the cavity and is made of silicon and which is secured to an insulating layer. A vacuum or at least one gas is provided in the cavity, wherein the insulating layer delimits the cavity at least on the stator electrode side facing away from the actuator electrode, and the stator electrode is secured to the insulating layer via at least one support structure which protrudes through the insulating layer and is made of silicon such that at least one intermediate gap with a vacuum or the at least one gas of the cavity is provided between the stator electrode and the insulating layer.

### FIELD

The present invention relates to a micromechanical component for a sensor device or microphone device. The present invention also relates to a production method for a micromechanical component for a sensor device or microphone device.

### BACKGROUND INFORMATION

The related art, such as German Patent Application No. DE 10 2020 200 335 A1, for example, describes micromechanical components in each case formed with a cavity, wherein at least one adjustable actuator electrode made of silicon and at least one stator electrode made of silicon secured to an insulating layer are arranged in the respective cavity.

### SUMMARY

The present invention provides a micromechanical component for a sensor device or microphone device and a production method for a micromechanical component for a sensor device or microphone device.

The present invention provides micromechanical components, or sensor or microphone devices equipped therewith, in which their stator electrode interacting with the associated actuator electrode is better stress-decoupled due to its securing (not necessarily exclusively) to the adjacent insulating layer by means of at least one support structure which protrudes through the insulating layer, forming at least one intermediate gap between the stator electrode and the insulating layer. Parasitic capacitances, which are described in more detail below, are also reduced with a micromechanical component realized by means of the present invention. In particular, with a micromechanical component according to the present invention, the stator electrode thereof remains unbent or minimally bent even under significant deformation of the insulating layer. With the micromechanical component according to the present invention, the stator electrode thus exhibits greater stability even under overload conditions. This increases the measuring accuracy of a sensor device realized by means of the present invention and reduces its susceptibility to errors. Furthermore, the present invention provides an additional wiring plane on the micromechanical components realized with it, which enables the production of cavity regions with completely circumferential etch stop delimitations.

With an advantageous example embodiment of the micromechanical component, the at least one intermediate gap in each case has a gap width extending from the stator electrode to the insulating layer, which gap width is greater than or equal to 5 nm. As can be seen from the following description, this improves the stress decoupling of the stator electrode and leads to a reduction in parasitic capacitances.

Preferably, according to an example embodiment of the present invention, the at least one support structure has a widening on a side of the insulating layer facing away from the stator electrode in each case. This ensures stable and reliable securing of the stator electrode to the insulating layer by means of the at least one support structure which protrudes through the insulating layer.

Advantageously, according to an example embodiment of the present invention, the at least one support structure penetrating the insulating layer can be connected to the insulating layer in a media-tight manner. This also enables a media-tight securing of the stator electrode to the insulating layer by means of the at least one support structure which protrudes through the insulating layer.

For example, the insulating layer can be made of silicon nitride, silicon-rich silicon nitride, silicon oxynitride, silicon carbide and/or aluminum oxide as the at least one electrically insulating material. In this case, the insulating layer exhibits high etch resistance to a liquid or gaseous etching medium commonly used for etching silicon dioxide. This makes it easier to expose the at least one intermediate gap between the stator electrode and the insulating layer by etching a silicon dioxide present therein.

With a further advantageous embodiment of the micromechanical component of the present invention, the cavity is delimited on its side facing away from the insulating layer by a membrane inner side of a membrane, wherein the membrane is curved outwardly or inwardly in the event of a pressure difference between a pressure present on its membrane outer side facing away from the membrane inner side and a reference pressure present in the cavity, and the actuator electrode is suspended on the membrane inner side. Thus, the membrane with the actuator electrode suspended on the membrane inner side can be used to measure the pressure on the membrane outer side or to detect sound waves impinging on the membrane outer side. Therefore, the embodiment of the micromechanical component described here can be used for a plurality of sensor devices and microphone devices.

According to an example embodiment of the present invention, in a preferred manner, the actuator electrode suspended on the membrane inner side of the membrane is structured out of a silicon layer, wherein at least one membrane stop structure protruding into the cavity is structured out of the same silicon layer such that an inner edge aligned with the actuator electrode and an outer edge anchored to at least one side wall of the cavity can be defined for the at least one membrane stop structure protruding into the cavity, and an inward curvature of the membrane into the cavity can be delimited by means of the at least one membrane stop structure. This can also be described by saying that, by supporting/catching the membrane curved inwardly into the cavity by means of the at least one membrane stop structure, an excess curvature of the membrane, in particular in the region of its membrane clamping, which conventionally often leads to damage to the membrane, is reduced/inhibited. Therefore, with the embodiment of the micromechanical component described here, the membrane can be formed with a comparatively large surface area and/or to be comparatively thin, without this being associated with a high risk of damage to the membrane due to an excess curvature of the membrane into the cavity. The side wall of the cavity can be understood as a wall of the cavity extending from the membrane inner side of the membrane to the insulating layer.

For example, in the case of the at least one membrane stop structure, in each case a minimum distance between the inner edge of the respective membrane stop structure and the outer edge of the same membrane stop structure can be greater than or equal to 50 nm. In this case, the at least one membrane stop structure can be used to reliably inhibit an excess curvature of the membrane into the cavity.

Alternatively or additionally, according to an example embodiment of the present invention, a reference electrode can also be secured to the insulating layer on a side of the single membrane stop structure facing away from the membrane or at least one of the membrane stop structures, wherein a reference sensor signal can be tapped or provided with respect to a reference capacitance present between the reference electrode and the associated membrane stop structure. Thus, the membrane stop structure can also be used to perform reference measurements to calibrate or verify a measurement carried out by means of the actuator electrode and the stator electrode and, if support structures are used on/under the membrane stop structure after the membrane is applied to the membrane stop structure, to measure higher pressures.

Similarly, according to an example embodiment of the present invention, the single membrane stop structure or at least one of the membrane stop structures can be secured to the insulating layer by at least one support structure such that a deflection of the membrane causes a deformation and/or deflection of the single membrane stop structure or at least one of the membrane stop structures, and that a reference sensor signal is changed with respect to a reference capacitance present between a reference electrode and the associated membrane stop structure. This increases the usability of the at least one membrane stop structure.

The advantages described above are also achieved by performing a corresponding production method for a component for a sensor device or microphone device. It is expressly pointed out that the production method can be further developed in accordance with the embodiments of the micromechanical component of the present invention explained above.

### BRIEF DESCRIPTION OF THE DRAWINGS

Further features and advantages of the present invention will be explained in the following with reference to the figures.

FIG. 1A to 1F show cross-sections of intermediate products to illustrate a first example embodiment of the production method of the present invention.

FIG. 2 shows a cross-section of an intermediate product to illustrate a second example embodiment of the production method of the present invention.

FIG. 3 shows a cross-section of an intermediate product to illustrate a third example embodiment of the production method of the present invention.

FIG. 4 shows a cross-section of an intermediate product to illustrate a fourth example embodiment of the production method of the present invention.

FIG. 5 shows a cross-section of an intermediate product to illustrate a fifth embodiment of the production method of the present invention.

FIGS. 6A and 6B show schematic representations of a first example embodiment of the micromechanical component of the present invention.

FIG. 7 shows a schematic representation of a second example embodiment of the micromechanical component of the present invention.

FIG. 8 shows a schematic representation of a third example embodiment of the micromechanical component of the present invention.

FIGS. 9A and 9B show schematic representations of a fourth example embodiment of the micromechanical component of the present invention.

### DETAILED DESCRIPTION OF EXAMPLE EMBODIMENTS

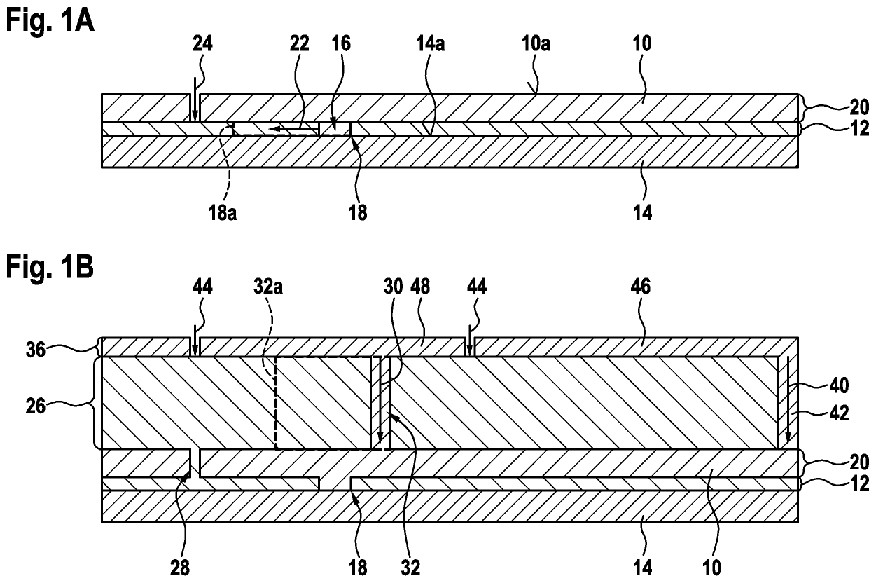

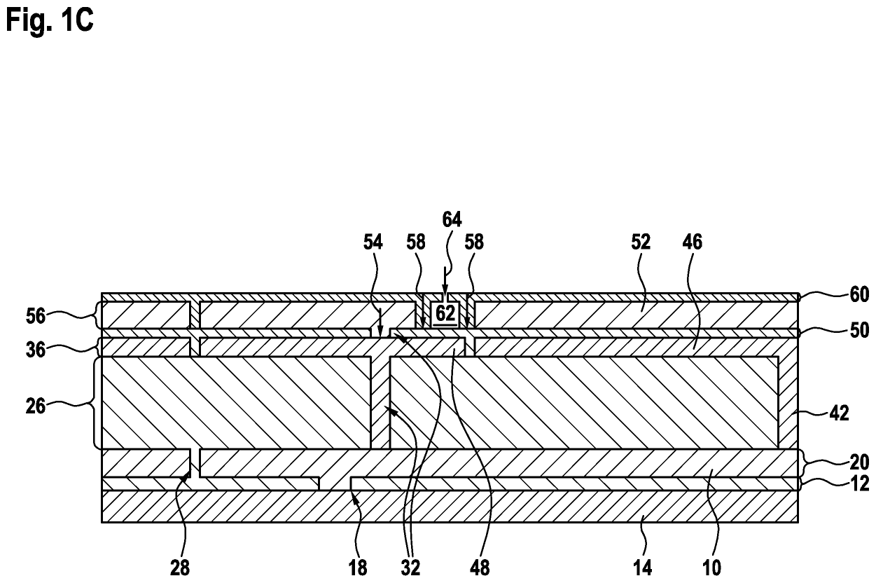

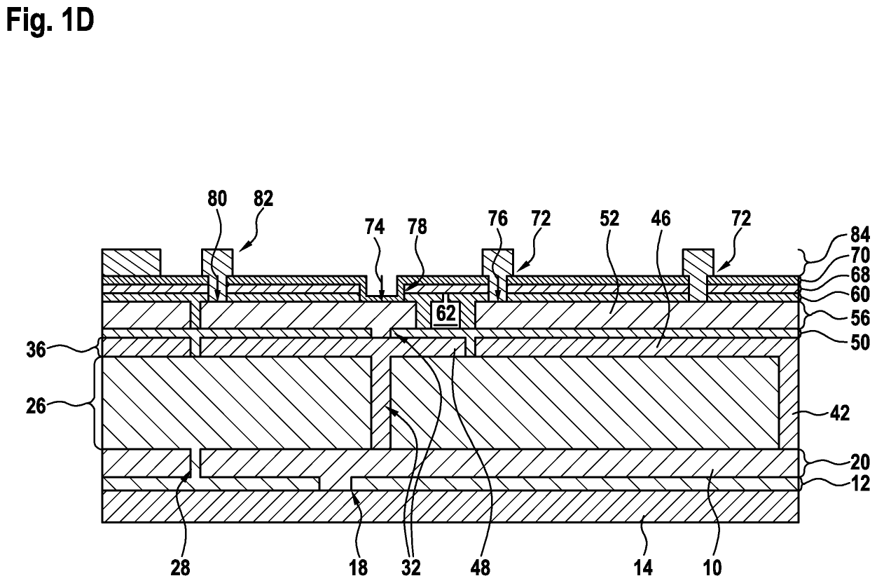

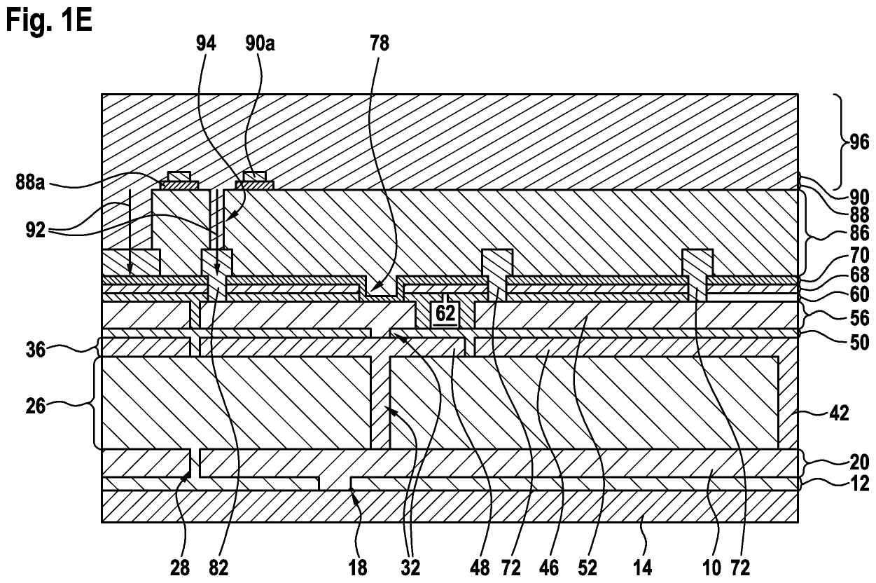

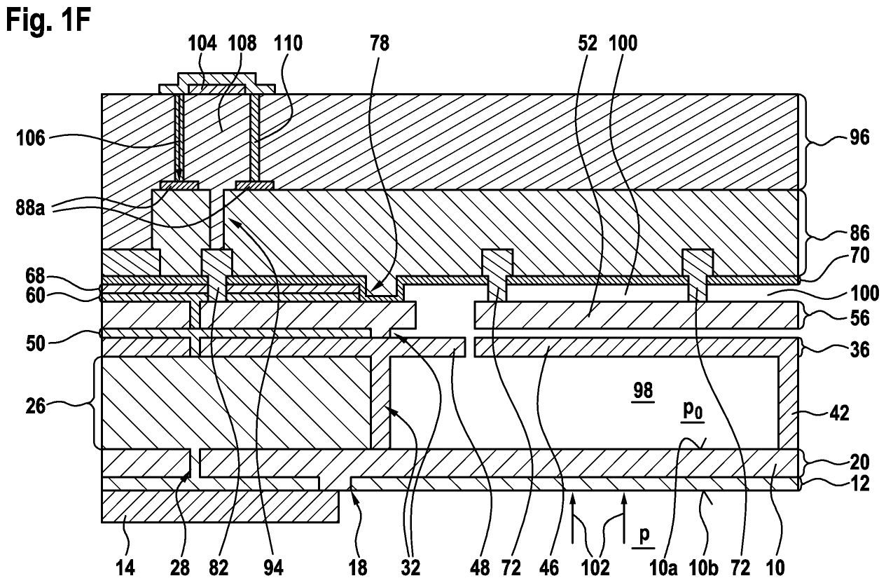

FIG. 1A to 1F show cross-sections of intermediate products to illustrate a first embodiment of the production method.

With the embodiment of the production method described here, a micromechanical component produced in this way is equipped, as an advantageous further development, with a membrane 10, the membrane inner side 10a of which is directly/immediately adjacent to a (later) cavity and delimits the cavity of the micromechanical component. To form the membrane 10, a first sacrificial material layer 12, such as a silicon dioxide layer 12, is first deposited on a substrate surface 14a of a substrate 14. The substrate 14 can be a silicon substrate 14, for example. Since the first sacrificial layer 12 is only to be etched in some regions to protect the membrane 10 in a later etching process to expose the membrane 10 and to define/create lateral etch stop structures 18, at least one continuous trench 16 is structured through the first sacrificial layer 12 after forming the first sacrificial layer 12, which in each case defines a position and a shape of an etch stop structure 18 formed later. Subsequently, the material of the membrane 10 and the at least one etch stop structure 18 is deposited as a membrane layer 20, such as a silicon/polysilicon layer 20. Thus, the at least one etch stop structure 18 can be easily formed from the material used simultaneously to form the membrane 10.

By means of the at least one etch stop structure 18, lateral etch delimitations can be defined when exposing the membrane 10 by removing the first sacrificial layer 12, and thus also the lateral dimensions of the membrane 10. This is illustrated by means of the arrow 22 in FIG. 1A. As outlined by means of the dashed line 18a, the at least one etch stop structure 18 can also be formed to be comparatively solid. When the production method described here is performed, the membrane 10 can be formed with a comparatively large surface area and/or to be comparatively thin compared to the related art, since, as explained in more detail below, damage to the membrane 10 by an excess curvature of the membrane 10, in particular in the region of the membrane clamping, is reduced/inhibited.

Then, at least one trench 24 is structured through the membrane layer 20, in which electrical insulation is later formed in each case. As can be seen in FIG. 1A, the at least one trench 24 can be used to electrically separate/insulate the membrane 10 from the surrounding membrane layer 20 and/or to create at least one electrical conductor path from the material of the membrane layer 20 for electrically connecting the membrane 10.

Subsequently, a second sacrificial layer 26, such as a silicon dioxide layer 26, is deposited on a side of the membrane layer 20 facing away from the substrate 14, as a result of which the at least one electrical insulation 28 is formed in the at least one trench 24. By structuring at least one continuous trench 30 through the second sacrificial layer 26, a position and a shape of the at least one anchoring region 32 of the membrane 10 can be defined. The at least one anchoring region 32 also realizes a lateral etch stop delimitation that encircles the (later) cavity. By means of the dashed line 32a, it is indicated that the at least one anchoring region 32 can also be formed to be comparatively solid, at least in some parts/regions.

Now, a first silicon layer/polysilicon layer 36 is deposited on a side of the second sacrificial layer 26 facing away from the substrate 14. By filling the at least one trench 30 in this way, the at least one anchoring region 32 of the membrane 10 is also formed. If desired, the at least one trench 30 can also be filled with a further layer made of silicon or polysilicon prior to the deposition of the first silicon layer 36 before depositing the first silicon layer 36 after the performing of a CMP step to remove the further layer made of silicon/polysilicon from the second sacrificial layer 26. In this way, a layer thickness of the first silicon layer 36 aligned perpendicular to the substrate surface 14a of the substrate 14 can be selected independently of the geometric dimensions of the structures to be filled in the second sacrificial layer 26. The membrane layer 20 and the first electrode layer 36 can optionally be placed at the same or a different electrical potential.

Advantageously, together with the at least one trench 30, at least one trench 40 can also be structured through the second sacrificial layer 26, in which at least one suspension structure 42 is formed by depositing the silicon layer 36. By means of a structuring of at least one trench 44 passing through the silicon layer 36, at least one actuator electrode 46 is structured out of the silicon layer 36. In particular, with the embodiment of the method described here, the actuator electrode 46 is suspended electrically and/or mechanically on the membrane inner side 10a of the membrane 10 via the at least one suspension structure 42, such that the actuator electrode 46 is/can be adjusted by means of a curvature of the membrane 10 during a later operation of the micromechanical component. As an advantageous further development, with the embodiment described here, at least one membrane stop structure 48 protruding into the later cavity is also structured out of the silicon layer 36. The function of the at least one membrane stop structure 48 is discussed in more detail below.

As can be seen in FIG. 1C, a third sacrificial layer 50, for example a silicon dioxide layer 50, is subsequently deposited on a side of the first silicon layer 36 facing away from the substrate 14. A layer thickness of the third sacrificial layer 50 aligned perpendicular to the substrate surface 14a of the substrate 14 defines a later distance between the actuator electrode 46 and a (later formed) stator electrode 52. By means of at least one trench 54 structured by the third sacrificial layer 50, the anchoring region 32 can be extended. Then, a second silicon layer/polysilicon layer 56 is deposited on a side of the third sacrificial layer 50 facing away from the substrate 14. The at least one trench 54 is also filled such that its filling can be used as an electrical contact structure and/or as an etch stop structure. Optionally, prior to the deposition of the second silicon layer 46, the at least one trench 54 can first be filled with a further layer made of silicon/polysilicon before the second silicon layer/polysilicon layer 56 is deposited on the third sacrificial layer 50 after the performing of a CMP step to remove the further layer made of silicon/polysilicon.

The stator electrode 52 is formed by means of at least one trench 58 structured by the second silicon layer/polysilicon layer 56. By depositing a fourth sacrificial layer 60, for example a silicon dioxide layer 60, on a side of the second silicon layer/polysilicon layer 56 facing away from the substrate 14, the at least one trench 58 is filled. Optionally, at least one hollow space 62 can now be formed within the second silicon layer/polysilicon layer 56 by first exposing at least one silicon region of the second silicon layer/polysilicon layer 56 delimited by at least two filled trenches 58 by means of at least one trench 64 structured by the fourth sacrificial layer 60, and then etching the at least one exposed silicon region through the at least one trench 64 by means of an isotropic silicon etching process. The formation of the at least one hollow space 62 facilitates the rapid and large-area distribution of a gaseous, HF-containing etching medium during a later sacrificial layer etching process. The intermediate product is shown in FIG. 1C.

The at least one hollow space 62 can subsequently be sealed by means of a fifth sacrificial layer 68, in particular a silicon dioxide layer 68. An insulating layer 70 is then deposited on a side facing away from the substrate 14 of at least one of the sacrificial layers 60 and 68. The insulating layer 70 is formed from at least one electrically insulating material and/or an electrically insulating material composition comprising at least two elements having in each case an electrical conductivity of less than 10⁻⁸ S/cm and/or a specific resistance of greater than 10⁸ Ω cm. In particular, the at least one electrically insulating material of the insulating layer 70 differs from the at least one material of the sacrificial layers 12, 26, 50, 60 and 68 and has a significantly higher etch resistance to the etching medium used in the sacrificial layer etching process than the at least one material of the sacrificial layers 12, 26, 50, 60 and 68. The insulating layer 70 can, for example, consist of silicon nitride, silicon-rich silicon nitride, silicon oxynitride, silicon carbide, aluminum oxide or a combination of at least two of these materials as its at least one electrically insulating material. The insulating layer 70 is deposited such that the insulating layer 70 delimits the (later) cavity at least on a side of the stator electrode 52 facing away from the actuator electrode 46.

To form a high etch resistance to the etching medium used in the sacrificial layer etching process, the at least one electrically insulating material of the insulating layer 70 can at least partially have a material/element composition and/or lattice structure that deviates from a stoichiometric material/element composition and have an electrical conductivity that deviates from a stoichiometric material/element composition and is greater than 10⁻⁸ S/cm and/or have a specific resistance of less than 10⁸ Ω cm. As is described in the technical literature, even small deviations in a stoichiometric material composition can lead to recognizable changes in the electrical conductivity and/or the specific resistance.

Optionally, prior to the deposition of the insulating layer 70, at least one trench 74 passing through at least one of the sacrificial layers 60 and 68 can be structured, which trench is at least partially filled with its at least one electrically insulating material during the subsequent deposition of the insulating layer 70. In this way, at least one lateral etch stop structure 78 can be formed for later sacrificial layer etching. Preferably, the at least one lateral etch stop structure 78 is formed in the region of the membrane anchoring 32.

In addition, the stator electrode 52 is secured to the insulating layer 70 on its side facing away from the actuator electrode 46. For this purpose, at least one support structure 72 made of silicon which protrudes through the insulating layer 70 is formed such that the stator electrode 52 is secured to the insulating layer 70 in a media-tight manner via the at least one support structure 72. To form the at least one support structure 72, at least one trench 76 passing through the layers 60, 68 and 70 is structured, which opens/ends at the stator electrode 52.

As an advantageous further development, together with the at least one trench 76, at least one further trench 80 can also be structured by the layers 60, 68 and 70 on a side of the at least one lateral etch stop structure 78 facing away from the at least one trench 76. Since the at least one lateral etch stop structure 78 is designed to be electrically insulating, the at least one trench 80 can be used to form at least one contact structure, through which electrical conductor paths of the later micromechanical component can be electrically contacted by means of a subsequently produced wiring plane 82 and/or electrically connected as desired over the entire chip surface and the anchoring region 32, without having to fear short circuits with other conductor paths in other silicon/polysilicon planes and/or conductive etch stop structures. By integrating the wiring plane 82 adjacent to the (later) cavity, but separated from it at least by the insulating layer 70, a more flexible wiring of the component parts of the (later) micromechanical component is achieved. The wiring plane 82 can be used, for example, to provide bond pad structures at any positions of the micromechanical component and/or to make electrical contact with the stator electrode 52 via the at least one support structure 72. Since the wiring plane 82 is located outside the (later) cavity, separated at least by the insulating layer 70, there is a high degree of design freedom with regard to its realizable wiring variants and the electrical connection options of structures/conductor paths inside/outside the (later) cavity region, in particular while maintaining etch stop conditions/etch stop delimitations defined on all sides for the cavity region to be created.

After forming the trenches 76 and 80, a third silicon layer/polysilicon layer 84 is subsequently deposited on a side of the insulating layer 70 facing away from the substrate 14, with the material of which the trenches 76 and 80 are filled.

Then, the at least one support structure 72 and the wiring plane 82 are formed/structured out of the silicon of the third silicon layer 84. Optionally, the trenches 76 and 80 can also be filled with a further layer made of silicon/polysilicon prior to the deposition of the third silicon layer 84, in which case the third silicon layer 84 is not deposited until after the performing of a CMP step to remove the further layer made of silicon/polysilicon on the insulating layer 70. In this way, a layer thickness of the third silicon layer 84 aligned perpendicular to the substrate surface 14a of the substrate 14 can be selected independently of the geometric dimensions of the trenches 76 and 80. FIG. 1D shows the intermediate product after the formation of the at least one support structure 72 and the wiring plane 82.

After the at least one support structure 72 and the wiring plane 82 are formed, they are completely covered with a sixth sacrificial layer 86, for example a silicon dioxide layer 86. An optional silicon nitride layer 88 can subsequently be formed on the surface of the sixth sacrificial layer 86 facing away from the substrate 14. Optionally, a silicon dioxide layer 90 can then be deposited directly on the silicon nitride layer 88. In this case, the (optional) silicon dioxide layer 90 can be structured such that at least one silicon dioxide region 90a of the silicon dioxide layer 90 remains only where the silicon nitride layer 88 is to be protected from an etching in a subsequently carried out etching process. Thus, the at least one silicon dioxide region 90a is used as a vertical etch stop. After the structuring of the (optional) silicon dioxide layer 90, a structuring of the (optional) silicon nitride layer 88 is effected such that at least one silicon nitride region 88a remains only at a respective location of at least one electrical insulation trench to be performed later. The at least one silicon nitride region 88a can be used as a moisture barrier in order to prevent moisture from later entering the sixth sacrificial layer 86 through the at least one electrical insulation trench during the operation of the micromechanical device. Alternatively, after the optional deposition of the silicon nitride layer 88 and/or the silicon dioxide layer 90, a structuring of the silicon nitride layer 88 and/or the silicon dioxide layer 90 can be omitted.

Subsequently, by means of a structuring of the sixth sacrificial layer 86, at least one trench 92 is formed through the sixth sacrificial layer 86 and possibly also through the silicon nitride layer 88 and/or the silicon dioxide layer 90, which defines a location and a position of at least one electrical contact and/or lateral etch stop structure 94 (formed later). Then, a fourth silicon layer/polysilicon layer 96 is deposited, with the material of which the at least one trench 92 is filled. Preferably, the fourth silicon layer/polysilicon layer 96 is designed to be mechanically stable and rigid in order to counteract deformations during later operation of the micromechanical component. High mechanical stability can be achieved, for example, by applying a correspondingly thick silicon layer/polysilicon layer 96. Preferably, the silicon of the fourth silicon layer/polysilicon layer 96 is deposited in a silicon epitaxy reactor. FIG. 1E shows the intermediate product.

It is also pointed out here that, with the intermediate product of FIG. 1E, parasitic capacitances, i.e., capacitances formed between the stator electrode 52 and the fourth silicon layer/polysilicon layer 96, are reduced.

After the deposition of the fourth silicon layer/polysilicon layer 96, at least one etch access channel (not shown) is formed in the fourth silicon layer/polysilicon layer 96. The at least one etching access channel is used to conduct the gaseous, HF-containing etching medium to expose the (later) cavity 98. A great deal of design freedom is guaranteed for the formation of at least one etching access channel. Subsequently, the sacrificial layer etching process can be carried out to expose the cavity 98. The etching medium spreads through the at least one etch access channel during the sacrificial layer etching process and removes regions of the sacrificial layers 26, 50, 60 and 68. The at least one hollow space 62 can significantly accelerate the sacrificial layer etching process. However, it is expressly pointed out that the etching medium does not affect/minimally affects the insulating layer 70.

After sacrificial layer etching, the at least one etch access channel can be sealed using conventional methods. By means of closing the at least one etching access channel, a vacuum or at least one gas is enclosed in the cavity 98. Therefore, a vacuum or the at least one gas of the cavity 98 is also present in at least one intermediate gap 100 formed by etching the sacrificial layers 60 and 68 between the stator electrode 52 and the insulating layer 70. Therefore, the stator electrode 52 is (substantially) self-supporting after performing the sacrificial layer etching and is only connected to the insulating layer 70 via the individual support structures 72. By securing the stator electrode 52 to the insulating layer 70 only at certain points, a deformation of the stator electrode 52 due to, for example, stress coupling/deformation of the fourth silicon layer 96, the sixth sacrificial layer 86 and the insulating layer 70 can be minimized or completely avoided.

Preferably, the closing of at least one etch access channel is effected by means of a laser seal method, with which the at least one etch access channel is closed by localized melting of silicon of the fourth silicon layer 96. Performing the laser seal method has the advantage that a particularly low reference pressure p₀ of nearly a vacuum can be enclosed in the cavity 98. Possibly, the etch access channel can also be located at the bottom of a recess provided in the fourth silicon layer 96, as a result of which mechanical contact of the silicon melted by means of a laser in the region of the etch access channel in a subsequent CMP step with a polishing pad and/or in subsequent manufacturing processes with handling systems can be avoided. After the closing of the at least one etch access channel, the fourth silicon layer 96 can optionally still be planarized by performing a grinding and/or CMP step and reduced in its layer thickness aligned perpendicular to the substrate surface 14a of the substrate 14. Alternatively or additionally, the substrate 14 can also be reduced in thickness by performing a grinding and/or CMP step, for example in order to reduce the etching time to expose the membrane 10.

By means of an opening 102 structured through the substrate 14, the first sacrificial layer 12 can be exposed in the region of the membrane 10. The etching process carried out for this purpose can stop on the first sacrificial layer 12. By locally removing the first sacrificial layer 12 using the at least one lateral etch stop structure 18, a membrane outer side 10b of the membrane 10 facing away from the cavity 98 or the membrane inner side 10a can be exposed. In this way, the membrane 10 is formed to be able to be curved such that the membrane 10 curves outwardly or inwardly in the event of a pressure difference between a pressure p present on the membrane outer side 10b and the reference pressure p₀ present in the cavity 98. As can be seen in FIG. 1F, when the production method described here is performed, the actuator electrode 46 and the stator electrode 52 are arranged in the cavity 98 such that the actuator electrode 46 can be adjusted within the cavity 98 by means of the inward or outward curvature of the membrane 10, while the stator electrode 52 is secured non-adjustably to the insulating layer 70 via the at least one support structure 72 which protrudes through the insulating layer 70.

Subsequently, at least one bond pad 104 can be arranged on the side of the fourth silicon layer 96 facing away from the substrate 14. The at least one bond pad 104 can, for example, be made of aluminum, aluminum-copper, aluminum-silicon-copper or gold. Moreover, between the minimum of one bond pad 104 and the fourth silicon layer/polysilicon layer 96, a diffusion barrier commonly used in semiconductor technology, or a commonly used layer system acting as a diffusion barrier, may be present. Then, at least one electrical insulation trench 106 is structured through the fourth silicon layer 96, in order to electrically insulate at least one silicon contact structure 108 mechanically and/or electrically contacted by the at least one bond pad 104 from the remainder of the fourth silicon layer 96. The at least one electrical insulation trench 106 can stop on the at least one silicon dioxide region 90a. Optionally, an electrically insulating material 110, such as silicon dioxide, silicon nitride, silicon oxynitride or silicon-rich silicon nitride, can then be filled into the at least one electrical insulation trench 106. By filling the at least one electrical insulation trench 106 with the at least one electrically insulating material 110, entry of moisture and entry and accumulation of particles in the at least one electrical insulation trench 106 can be prevented.

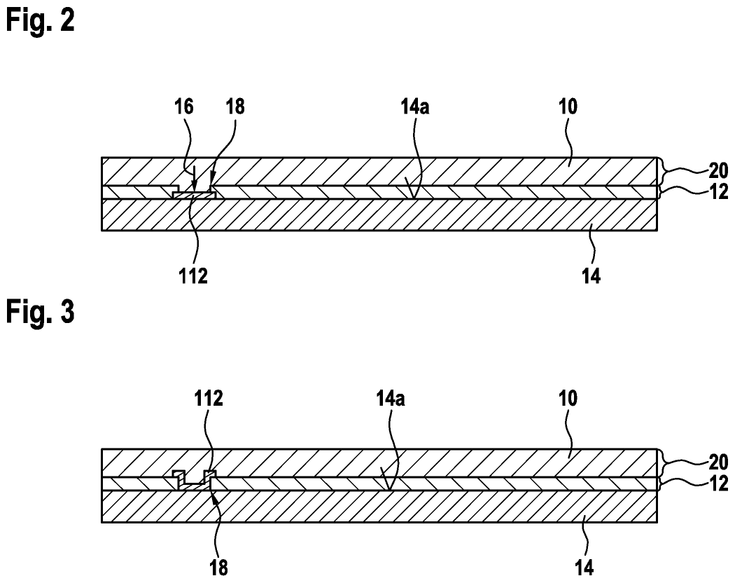

FIG. 2 shows a cross-section of an intermediate product to illustrate a second embodiment of the production method.

As can be seen in FIG. 2, the at least one lateral etch stop structure 18 can also consist at least partially of an electrically insulating material 112, such as silicon nitride, silicon oxynitride, silicon-rich silicon nitride, silicon carbide and/or aluminum oxide, or a combination of at least two of these materials. For this purpose, prior to the deposition of the first sacrificial layer 12 on the substrate surface 14a of the substrate 14, a layer of the electrically insulating material 112 is deposited and removed from the substrate surface 14a except for the at least one later region of the at least one lateral etch stop structure 18. Only then is the first sacrificial layer 12 deposited.

By means of the formation of the at least one lateral etch stop structure 18 described here, the membrane layer 20 and the substrate 14 can optionally be placed at the same or a different electrical potential.

With respect to further method steps of the production method of FIG. 2, reference is made to the description of FIG. 1.

FIG. 3 shows a cross-section of an intermediate product to illustrate a third embodiment of the production method.

With the production method schematically shown by means of FIG. 3, the first sacrificial layer 12 is formed on the substrate surface 14a of the substrate 14 prior to the deposition of the electrically insulating material 112 and is subsequently completely removed in the region of the at least one later lateral etch stop structure 18. Then, the electrically-insulating material 112 is deposited, which is subsequently removed from a surface of the first sacrificial layer 12 facing away from the substrate 14 except for the at least one region of the at least one lateral etch stop structure 18.

The formation of the at least one lateral etch stop structure 18 illustrated in FIG. 3 can also be used to place the membrane layer 20 and the substrate 14 optionally at the same or a different electrical potential.

With respect to further method steps of the production method of FIG. 3, reference is made to the description of FIGS. 1 and 2.

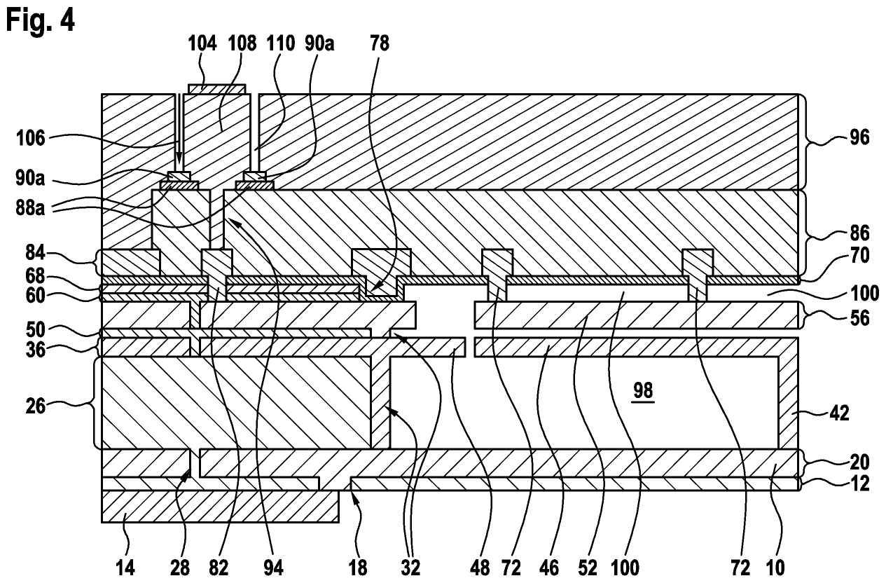

FIG. 4 shows a cross-section of an intermediate product to illustrate a fourth embodiment of the production method.

FIG. 4 shows a filling of the etch stop structure 78 with material of the third silicon layer 84 and/or with material of the sixth sacrificial layer 86. After the filling of the etch stop structure 78 with material of the third silicon layer 84 and/or with material of the sixth sacrificial layer 86, a further optional planarization of the surface of the silicon layer 84 and/or the sixth sacrificial layer 86 can be effected with the aid of a CMP step. Alternatively, the hatched region in FIG. 4 can also be (completely) filled with the material of the insulating layer 70.

With respect to further method steps of the production method of FIG. 4, reference is made to the description of FIGS. 1 to 3.

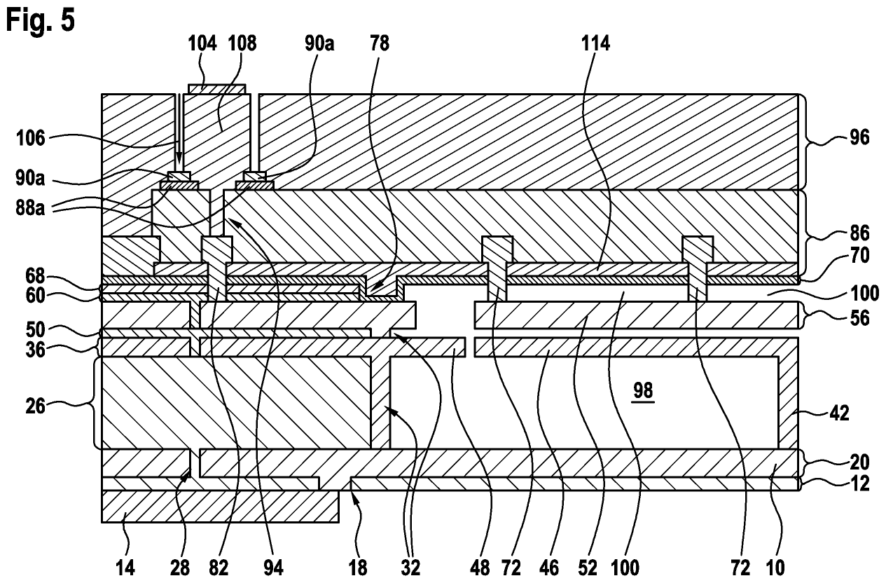

FIG. 5 shows a cross-section of an intermediate product to illustrate a fifth embodiment of the production method.

By means of FIG. 5, an optional deposition of a silicon dioxide 114, for example a TEOS oxide, prior to the structuring of the at least one trench 76 and 80 is schematically shown. After the deposition of the silicon dioxide 114 and prior to the structuring of the at least one trench 76 and 80, further optionally a planarization of the surface of the silicon dioxide 114 can be effected with the aid of a CMP step. The CMP step can be carried out such that it stops on the insulating layer 70 and silicon dioxide 114 only remains in recesses in the region of the etch stop structure 78. The hatched region in FIG. 4 is (completely) filled with silicon dioxide 114.

With respect to further method steps of the production method of FIG. 5, reference is made to the description of FIGS. 1 to 4.

When performing the production methods described above, all silicon layers 20, 36, 56, 84 and 96 can be provided with at least one dopant to increase their (local) conductivity. Furthermore, a polishing step, such as a chemical-mechanical polishing step (CMP step) in particular, can in principle be carried out after each deposition of a silicon layer 20, 36, 56, 84 and 96.

With all the production methods described above, the at least one membrane stop structure 48 protruding into the cavity 98 can be structured out of the first silicon layer 36 such that an inner edge aligned with the actuator electrode 46 and an outer edge anchored to at least one side wall of the cavity 98 can be defined for the at least one membrane stop structure 48 protruding into the cavity 98. The advantageous mode of operation of the at least one membrane stop structure 48 for delimiting an inward curvature of the membrane 10 into the cavity 98, in particular in the clamping/anchoring region of the membrane 10, will be discussed with reference to the following embodiments.

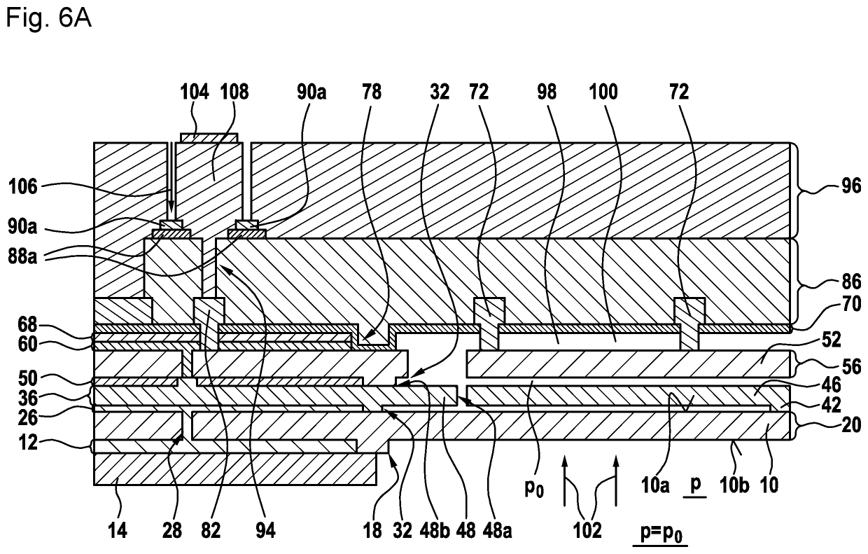

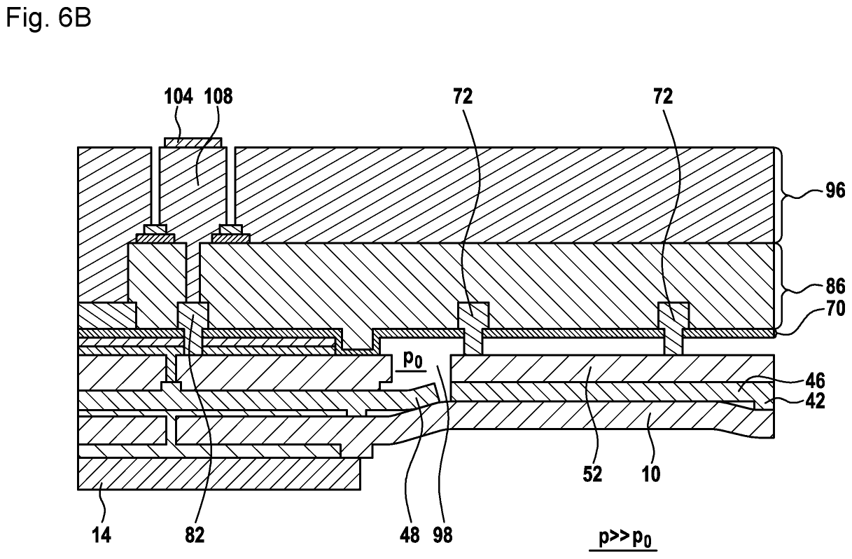

FIGS. 6A and 6B show schematic representations of a first embodiment of the micromechanical component.

The micromechanical component shown schematically in FIG. 6A has an actuator electrode 46 made of silicon/polysilicon arranged adjustably on and/or in its cavity 98 and a stator electrode 52 made of silicon/polysilicon arranged in the (same) cavity 98. There is a vacuum or at least one gas in the cavity 98. The stator electrode 52 is secured to an insulating layer 70 on a side of the stator electrode 52 facing away from the actuator electrode 46, which delimits the cavity 98 at least on the side of the stator electrode 52 facing away from the actuator electrode 46. The insulating layer 70 is formed from at least one electrically insulating material having in each case an electrical conductivity of less than 10⁻⁸ S/cm and/or a specific resistance of greater than 10⁸ Ω cm. The insulating layer 70 can be, for example, silicon nitride, silicon oxynitride, silicon-rich silicon nitride, silicon oxynitride, silicon carbide and/or aluminum oxide as the at least one electrically insulating material.

In addition, the stator electrode 52 is secured to the insulating layer 70 via (at least) one support structure 72 made of silicon which protrudes through at least the insulating layer 70 such that at least one intermediate gap 100 with a vacuum or the at least one gas of the cavity 98 is provided between the stator electrode 52 and the insulating layer 70. Thus, even with the micromechanical component described here, a deformation of the stator electrode 52 due to, for example, stress coupling/deformation of the micromechanical component is minimized or completely avoided by the securing of the stator electrode 52 to the insulating layer 70 only at certain points via the at least one support structure 72. Preferably, the at least one intermediate gap 100 in each case has a gap width extending from the stator electrode 52 to the insulating layer 70, which is designed such that, in the event of stress coupling/deformation of the micromechanical component, mechanical contact between the stator electrode 52 and the insulating layer 70 outside the at least one support structure is inhibited/prevented. This improves the stress decoupling of the stator electrode 52. In addition, the at least one support structure 72 can in each case have a widening on a side of the insulating layer 70 facing away from the stator electrode 52, which favors/strengthens a hold of the stator electrode 52 on the insulating layer 70 via the at least one support structure 72.

In particular, with the micromechanical component described here, the cavity 98 is delimited on its side opposite the insulating layer 70 by a membrane inner side 10a of a membrane 10. In addition, in the event of a pressure difference between a pressure p present on the membrane outer side 10b facing away from the membrane inner side 10a and a reference pressure p₀ present in the cavity 98, the membrane 10 is curved outwardly or inwardly, as a result of which the actuator electrode 46 suspended on the membrane inner side 10a of the membrane 10 is/can be adjusted. The actuator electrode 46 suspended on the membrane inner side 10a of the membrane 10 is structured out of a silicon layer 36. FIG. 6A shows the membrane 10 at equal pressure (p=p₀) on its membrane inner side 10a and its membrane outer side 10b.

Advantageously, the micromechanical component described here also has at least one membrane stop structure 48 protruding into the cavity 98. The at least one membrane stop structure 48 can, for example, be structured out of the silicon layer 36 such that in each case an inner edge 48a aligned with the actuator electrode 46 and an outer edge 48b anchored to at least one side wall of the cavity 98 can be defined for the at least one membrane stop structure 48 protruding into the cavity 98. The mobility of the at least one membrane stop structure that is self-supporting or clamped on one side can be flexibly defined by its lateral dimensions, its thickness and/or its shaping.

As can be seen in FIG. 6B, even if the pressure p on the membrane outer side 10b is significantly higher than the reference pressure p₀ (p>>p₀), an inward curvature of the membrane 10 into the cavity 98 can be reduced/delimited at least in the region of the clamping/anchoring of the membrane 10 by means of the at least one membrane stop structure 48. The supporting/catching of the membrane 10 curved inwardly into the cavity 98 by means of the at least one membrane stop structure 48 shown in FIG. 6B reduces/prevents/inhibits an excess curvature of the membrane 10 at least in the region of the clamping/anchoring of the membrane 10, which in the related art can often lead to damage to the membrane 10. Therefore, with the embodiment of the micromechanical component described here, the membrane 10 can be formed with a comparatively large surface area and/or to be comparatively thin, without this being associated with a high risk of damage to the membrane 10 due to an excess curvature of the membrane 10 into the cavity 98.

In particular by means of a comparatively thin formation of a sacrificial layer 26 located between a membrane layer 20 and the silicon layer 36, the excess curvature of the membrane 10 into the cavity 98 can be delimited at an early stage. Thus, in the event of an overload, the membrane 10 can “lean” against the at least one membrane stop structure 48 even after a small and still uncritical deflection, as a result of which damage to the membrane 10 is avoided by means of support and stabilization.

As an alternative to the embodiment of FIGS. 6A and 6B, the at least one membrane stop structure 48 can also have regions of different thicknesses. In particular, the at least one membrane stop structure 48 can be formed to taper into the cavity 98 starting from the clamping/anchoring region of the membrane 10. Preferably, the region of the at least one membrane stop structure 48 with the smallest thickness has the greatest distance from the membrane inner side 10a.

With respect to further features of the micromechanical component of FIGS. 6A and 6B and their advantages, reference is made to the description of FIGS. 1 to 5.

In order to realize a measurement characteristic that is as linear as possible, it is often also advantageous to select the geometric design of the at least membrane stop structure 48 and/or the silicon dioxide layer 26 such that a large-area mechanical contact between the membrane inner side 10a and the at least membrane stop structure 48 is only effected if a movement of the actuator electrode 46 in the direction of the stator electrode 52 is no longer possible (i.e., the actuator electrode 46 rests on the stator electrode 52).

Alternatively, a geometrical design of the membrane stop structure 48 and/or the silicon dioxide layer 26 can be such that, at a defined external pressure p, mechanical contact between the membrane inner side 10a and the at least one membrane stop structure 48 is effected before the actuator electrode 46 rests on the stator electrode 52. The mechanical contact between the membrane inner side 10a and the at least one membrane stop structure 48 achieves a local stiffening of the membrane 10, as a result of which its membrane characteristics are influenced, allowing for the measurement of significantly higher external pressures. With this design variant, comparatively low external pressures can be measured precisely and a large pressure measurement range can be realized.

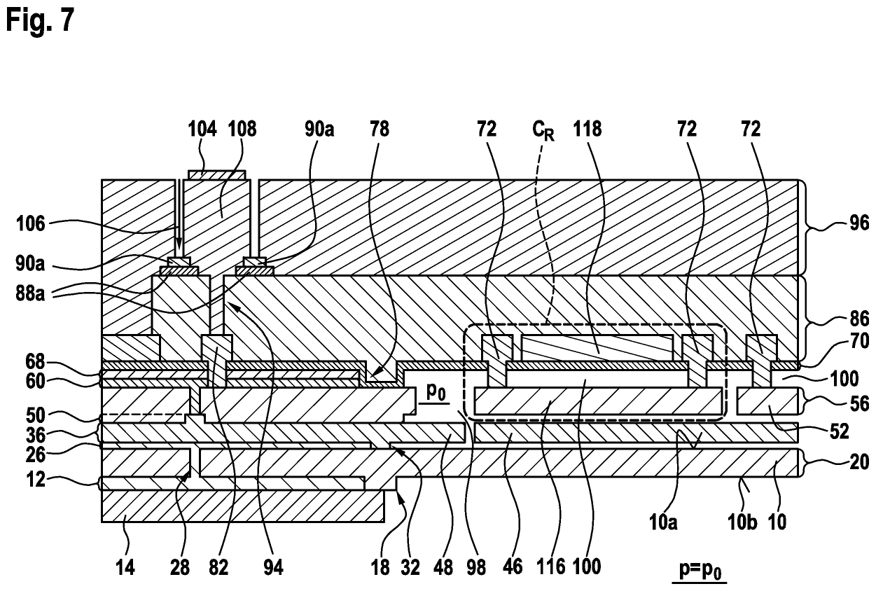

FIG. 7 shows a schematic representation of a second embodiment of the micromechanical component.

With the micromechanical component described here, the stator electrode 52 and a first reference electrode 116 are formed from a silicon layer/polysilicon layer 56. The first reference electrode 116 is secured to the insulating layer 70 in a media-tight manner via at least one (further) support structure 72 made of silicon which protrudes through the insulating layer 70. A second reference electrode 118 is arranged on a side of the insulating layer 70 facing away from the first reference electrode 116. In this way, in addition to the measuring capacitance from the actuator electrode 46 and the stator electrode 52, a reference capacitance CR comprising the first reference electrode 116 and the second reference electrode 118 is also formed on the micromechanical component. The first reference electrode 116 can be spanned, at least in some regions, by the actuator electrode 46 and/or the at least one membrane stop structure 48. Alternatively, prior to the deposition of the third silicon layer/polysilicon layer 84 within the reference electrode region of the reference electrode 118, the insulating layer 70 can be removed at least in some regions.

With respect to further features of the micromechanical component of FIG. 7 and their advantages, reference is made to the description of FIGS. 1 to 6.

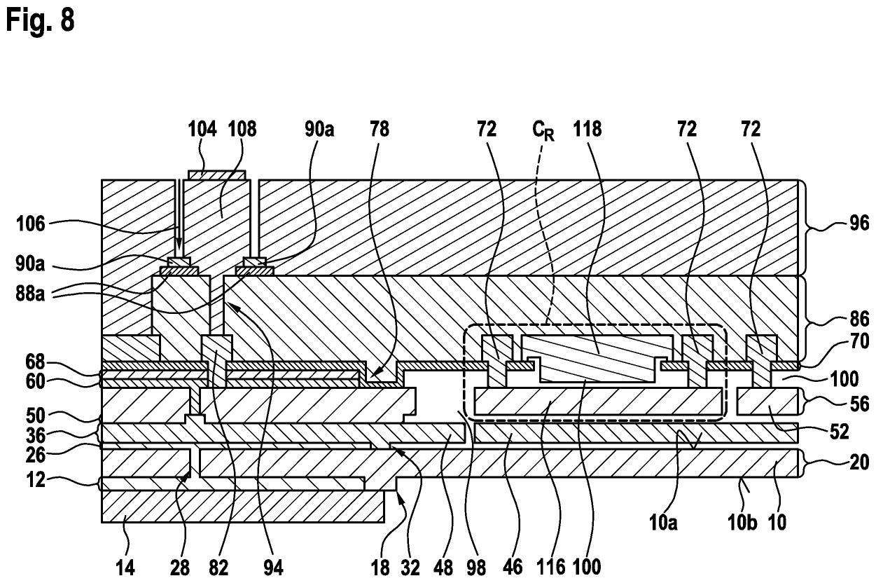

FIG. 8 shows a schematic representation of a third embodiment of the micromechanical component.

With the micromechanical component of FIG. 8, prior to the deposition of the third silicon layer/polysilicon layer 84 within the reference electrode region of the second reference electrode 118, the insulating layer 70 and the fourth sacrificial layer 60 are removed at least in some regions by an etching process. The etching process stops on the second silicon layer/polysilicon layer 56. Immediately after the removal of the insulating layer 70 and the fourth sacrificial layer 60, a further silicon dioxide layer is deposited and structured such that the third silicon layer/polysilicon layer 84 is brought into contact with the insulating layer 70 at least in the circumferential edge region of the second reference electrode 118. Thus, when etching the sacrificial layers 26, 50, 60, 68 made of silicon dioxide and the further silicon dioxide layer, an etching on the sixth sacrificial layer 86 made of silicon dioxide can be avoided.

Then, the at least one trench 76 and the at least one further trench 80 can be formed and the third silicon layer/polysilicon layer 84 can be deposited. Optionally, a CMP step can be carried out subsequently, which produces a flat surface and a desired layer thickness of the third silicon layer/polysilicon layer 84. Advantageously, the distance between the first reference electrode 116 and the second reference electrode 118 can be selected independently of the layer thicknesses of the sacrificial layers 12, 26, 50, 60 and 68 via the layer thickness of the further silicon dioxide layer.

With respect to further features of the micromechanical component of FIG. 8 and their advantages, reference is made to the description of FIGS. 1 to 7.

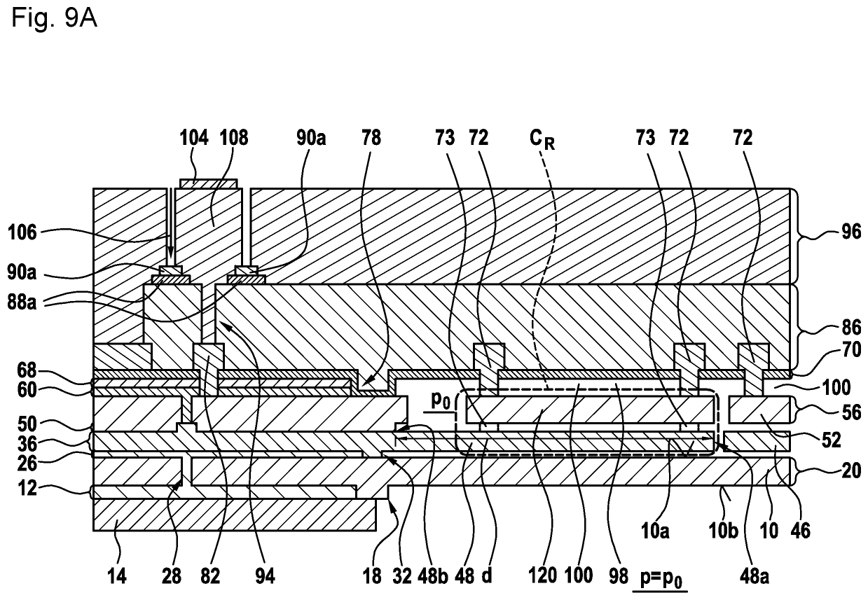

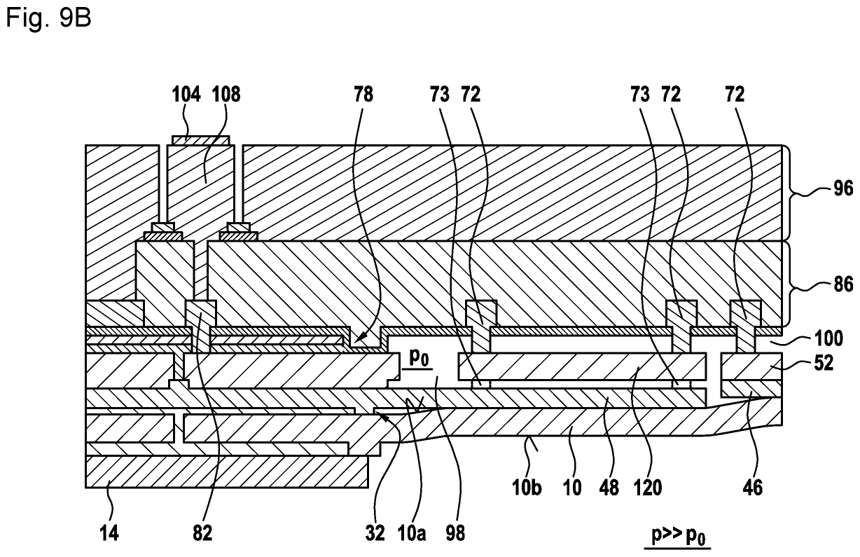

FIGS. 9A and 9B show schematic representations of a fourth embodiment of the micromechanical component.

With the micromechanical component of FIGS. 9A and 9B, in each case a minimum distance d of the inner edge 48a of the membrane stop structure 48 from the outer edge 48b of the same membrane stop structure 48 is greater than or equal to 50 nm in the case of its at least one membrane stop structure 48. This can be used advantageously. In particular, a reference electrode 120 is secured to the insulating layer 70 on a side of at least one of the membrane stop structures 48 facing away from the membrane 10 such that a reference sensor signal can be tapped or provided with respect to a reference capacitance present between the reference electrode 120 and the associated membrane stop structure 48. By means of the multifunctionality of the membrane stop structure 48, further components can be dispensed with (compare FIG. 8 with the second reference electrode 118 with FIG. 9A).

As can be seen in FIG. 9B, despite its multifunctionality, the membrane stop structure 48 can still be used advantageously to support/catch the membrane 10 curved inwardly into the cavity 98. With the component shown in FIGS. 9A and 9B, the at least one membrane stop structure 48 can optionally also be secured to the insulating layer 70 by at least one support structure 73, wherein the support structure 73 can optionally be formed like the support structure 72, in order to be able to counteract the deformation of the at least one membrane stop structure 48 during measurement operation and to be able to ensure a defined distance between the at least one membrane stop structure 48 and the reference electrode 120. If the at least one membrane stop structure 48 is connected to the insulating layer 70 via at least one support structure 73, a mechanical and/or electrical interruption of the at least one membrane stop structure 48 between the anchoring region 32 of the membrane 10 and the region of the reference electrode 120 can be effected at least in some regions. If the support structure 73 is formed to protrude through the insulating layer in the same way as the support structure 72, at least one membrane stop structure 48 that is mechanically and/or electrically separated from the anchoring region 32 can be electrically contacted. In the event that the at least one membrane stop structure 48 has support structures 73 in the region of the reference electrode 120, the actuator electrode 46 rests on the stator electrode 52 and the membrane 10 rests on the at least one membrane stop structure 48 in the region of the reference electrode 120, it can be achieved by suitable selection of the position of the support structures 73 supporting the at least one membrane stop structure 48 that the reference capacitance structure CR can be used to measure (significantly) higher external pressures p. Through the position of the support structures 73 and the selected thickness of the first silicon/polysilicon layer 36, which is also used to form the at least one membrane stop structure 48, the external pressure-dependent deformation of the membrane stop structure 48, and thus the pressure-dependent capacitance or capacitance change in the region of the reference capacitance structure CR, can be influenced. This enables sensitive and precise measurement of low external pressures p and a large pressure measurement range.

With respect to further features of the micromechanical component of FIGS. 9A and 9B and their advantages, reference is made to the description of FIGS. 1 to 8.

The micromechanical components produced using the production methods described above and the micromechanical components described below are each suitable for a sensor device and a microphone device, in particular for a capacitive pressure sensor. In order to increase the sensing sensitivity of the respective sensor device, two measuring capacitances sharing a cavity 98, each consisting of an actuator electrode 46 and a stator electrode 52, can be connected in a Wheatstone bridge.

Possibly, the common cavity of the two measuring capacitances can also be realized via a channel structure formed between two cavities 98. In addition, a higher membrane stability is achieved with all micromechanical components according to the present invention. Furthermore, the integration of the additional wiring plane 82 enables more flexible wiring of the individual component parts.

Although this is not illustrated in the figures, at least one circumferential trench can still be/is structured in each of the micromechanical components described above to realize stress decoupling. Alternatively or additionally, the at least one bond pad 104 can be formed as a recessed bond pad 104 by locally removing the fourth silicon layer 96.

Since the at least one membrane stop structure 48 inhibits an excess curvature of the membrane 10 into the respective cavity 98, in particular in the region of the clamping/anchoring of the membrane 10, the membrane 10 can be formed with a comparatively large surface area and/or to be comparatively thin and with a relatively low bending stiffness for each of the micromechanical components. Therefore, the respective micromechanical component is particularly suitable for a low-pressure sensor with a comparatively thin membrane 10 and with a high overpressure resistance.

1-15. (canceled)

16. A micromechanical component for a sensor device or microphone device comprising:
an actuator electrode, which is adjustably arranged on and/or in a cavity of the micromechanical component and is made of silicon; and
a stator electrode, which is arranged in the cavity and is made of silicon and which is secured to an insulating layer on a side of the stator electrode facing away from the actuator electrode;
wherein a vacuum or at least one gas is provided in the cavity,
and wherein the insulating layer delimits the cavity at least on the side of the stator electrode facing away from the actuator electrode, and
the stator electrode is secured to the insulating layer via at least one support structure which protrudes through the insulating layer and is made of silicon such that at least one intermediate gap with a vacuum or the at least one gas of the cavity is provided between the stator electrode and the insulating layer.

17. The micromechanical component according to claim 16, wherein the at least one intermediate gap in each case has a gap width extending from the stator electrode to the insulating layer which is greater than or equal to 5 nm.

18. The micromechanical component according to claim 16, wherein the at least one support structure has a widening on a side of the insulating layer facing away from the stator electrode in each case.

19. The micromechanical component according to claim 16, wherein the at least one support structure penetrating the insulating layer is connected to the insulating layer in a media-tight manner.

20. The micromechanical component according to claim 16, wherein the insulating layer is made of silicon nitride and/or silicon-rich silicon nitride and/or silicon oxynitride and/or silicon carbide and/or aluminum oxide, as an at least one electrically insulating material.

21. The micromechanical component according to claim 16, wherein the insulating layer is formed from at least one electrically insulating material having in each case an electrical conductivity of less than 10⁻⁸ S/cm and/or a specific resistance of greater than 10⁸ Ω cm.

22. The micromechanical component according to claim 16, wherein the insulating layer is formed from at least one electrically insulating material having in each case an electrical conductivity of greater than 10⁻⁸ S/cm and/or a specific resistance of less than 10⁸ Ω cm.

23. The micromechanical component according to claim 16, wherein the cavity is delimited on a side facing away from the insulating layer by a membrane inner side of a membrane, and the membrane is curved outwardly or inwardly in the event of a pressure difference between a pressure present on its membrane outer side facing away from a membrane inner side and a reference pressure present in the cavity, and the actuator electrode is suspended on the membrane inner side of the membrane.

24. The micromechanical component according to claim 23, wherein the actuator electrode suspended on the membrane inner side of the membrane is structured out of a silicon layer, and at least one membrane stop structure protruding into the cavity is structured out of the same silicon layer in such a way that an inner edge aligned with the actuator electrode and an outer edge anchored to at least one side wall of the cavity can be defined for the at least one membrane stop structure protruding into the cavity, and an inward curvature of the membrane into the cavity can be delimited by the at least one membrane stop structure.

25. The micromechanical component according to claim 24, wherein a minimum distance between an inner edge of each at least one membrane stop structure and an outer edge of the same membrane stop structure is greater than or equal to 50 nm.

26. The micromechanical component according to claim 24, wherein a reference electrode is secured to the insulating layer on a side of the membrane stop structure facing away from the at least one of the membrane stop structures, and wherein a reference sensor signal can be tapped or provided with respect to a reference capacitance present between the reference electrode and the associated membrane stop structure.

27. The micromechanical component according to claim 24, wherein the at least one of the membrane stop structures is secured to the insulating layer by at least one support structure such that a deflection of the membrane causes a deformation and/or deflection of at least one of the at least one membrane stop structure, and that a reference sensor signal is changed with respect to a reference capacitance present between a reference electrode and the associated membrane stop structure.

28. A production method for a micromechanical component for a sensor device or microphone device, comprising the following steps:
arranging an actuator electrode made of silicon on and/or in a cavity of the micromechanical component such that the actuator electrode is adjustable; and
arranging a stator electrode made of silicon in the cavity, wherein the stator electrode is secured on a side of the stator electrode facing away from the actuator electrode to an insulating layer which delimits the cavity at least on the side of the stator electrode facing away from the actuator electrode; and
enclosing a vacuum or at least one gas in the cavity;
wherein the stator electrode is secured to the insulating layer via at least one support structure made of silicon which protrudes through the insulating layer such that at least one intermediate gap with a vacuum or the at least one gas of the cavity is provided between the stator electrode and the insulating layer.

29. The production method according to claim 28, further comprising:
forming a membrane, a membrane inner side of the membrane delimiting the cavity on a side facing away from the insulating layer such that the membrane is curved outwardly or inwardly in the event of a pressure difference between a pressure present on its membrane outer side facing away from the membrane inner side and a reference pressure present in the cavity;
wherein the actuator electrode is suspended from the membrane inner side of the membrane.

30. The production method according to claim 29, wherein the actuator electrode suspended on the membrane inner side of the membrane is structured out of a silicon layer, and at least one membrane stop structure protruding into the cavity is structured out of the same silicon layer such that an inner edge aligned with the actuator electrode and an outer edge anchored to at least one side wall of the cavity can be defined for the at least one membrane stop structure protruding into the cavity, and an inward curvature of the membrane into the cavity is delimited by the at least one membrane stop structure.
